(19) United States
(12) Patent Application Publication
(10) Pub. No.: US 2005/0173803 A1
(43) Pub. Date: Aug. 11, 2005

(54) Interlayer adhesion promoter for low k materials

(76) Inventors: Victor Lu, Santa Cruz, CA (US); Roger Y. Leung, San Jose, CA (US); Wenya Fan, Campbell, CA (US); Ananth Naman, San Jose, CA (US); De-Ling Zhou, Sunnyvale, CA (US)

Correspondence Address: Richard S Roberts, P O Box 484, Princeton, NJ, 08542-0484, US

(21) Appl. No.: 10/517,575

(22) PCT Filed: Sep. 20, 2002
(86) PCT No.: PCT/US02/29975

(51) Int. Cl. H01L 21/4763; H01L 23/48; H01L 29/40

(52) U.S. Cl. 257/759; 257/760; 438/623; 438/624

(57) ABSTRACT

The invention relates to the production of multilayered dielectric structures and to semiconductor devices and integrated circuits comprising these structures. The structures of the invention are prepared by adhering a porous dielectric layer to a substantially nonporous capping layer via an intermediate adhesion promoting dielectric layer. A multilayered dielectric structure is prepared which has a porous dielectric layer which has a porosity of about 10% or more; b) an adhesion promoting dielectric layer on the porous dielectric layer which has a porosity of about 10% or less; and a substantially nonporous capping layer on the adhesion promoting dielectric layer.

### BACKGROUND OF THE INVENTION

1. Field of the Invention

The present invention relates to the production of multilayered dielectric structures and to semiconductor devices and integrated circuits comprising these structures. The structures of the invention are prepared by adhering a porous dielectric layer to a substantially nonporous capping layer via an intermediate adhesion promoting dielectric layer.

2. Description of the Related Art

As feature sizes in integrated circuits are reduced to 0.15 μm and below, problems with interconnect RC delay, power consumption and signal cross-talk have become increasingly difficult to resolve. It is believed that the integration of low dielectric constant materials for interlevel dielectric (ILD) and intermetal dielectric (IMD) applications will help to solve these problems. While there have been previous efforts to apply low dielectric constant materials to integrated circuits, there remains a longstanding need in the art for further improvements in processing methods and in the optimization of both the dielectric and mechanical properties of such materials used in the manufacture of integrated circuits.

One type of material with a low dielectric constant is nanoporous silica films which is prepared from silicon containing pre-polymers by a spin-on sol-gel technique. Air has a dielectric constant of 1, and when air is introduced into a suitable silica material having a nanometer-scale pore structure, such films can be prepared with relatively low dielectric constants (“k”). Nanoporous silica materials are attractive because such materials have demonstrated high mechanical strength as indicated by modulus and stud pull data. Mechanical properties can be optimized by controlling the pore size distribution of the porous film. Nanoporous silica materials are attractive because it is possible to control the pore size, and hence the density, mechanical strength and dielectric constant of the resulting film material. In addition to a low k, nanoporous films offer other advantages including thermal stability to 900° C.; substantially small pore size; preparation from materials that are widely used in semiconductors; the ability to “tune” the dielectric constant over a wide range; and deposition can be achieved using tools similar to those employed for conventional spin-on glass processing.

Thus, high porosity in silica materials leads to a lower dielectric constant than would otherwise be available from the same materials in non-porous form. An additional advantage is that additional compositions and processes may be employed to produce nanoporous films while varying the relative density of the material. Other materials requirements include the need to have all pores substantially smaller than circuit feature sizes, the need to manage the strength decrease associated with porosity, and the role of surface chemistry on dielectric constant and environmental stability.

Nanoporous silica films have previously been fabricated by a number of methods. For example, nanoporous films have been prepared using a mixture of a solvent and a silica precursor, which is deposited on a substrate suitable for the purpose. Usually, a precursor in the form of, e.g., a spin-on-glass composition is applied to a substrate, and then polymerized in such a way as to form a dielectric film comprising nanometer-scale voids. When forming such nanoporous films, e.g., by spin-coating, the film coating is typically catalyzed with an acid or base catalyst and water to cause polymerization/gelation (“aging”) during an initial heating step. In order to achieve maximum strength through pore size selection, a low molecular weight porogen is used.

Density (or the inverse, porosity) is the key parameter of nanoporous films that controls the dielectric constant of the material, and this property is readily varied over a continuous spectrum from the extremes of an air gap at a porosity of 100% to a dense silica with a porosity of 0%. As density increases, dielectric constant and mechanical strength increase but the degree of porosity decreases, and vice versa. This suggests that the density range of nanoporous films must be optimally balanced between the desired range of low dielectric constant and the mechanical properties acceptable for the desired application.

One of the major difficulties in integrating porous low k materials, whether CVD (“Chemical Vapor Deposition”) or spin-on glasses is their adhesion to either a CVD capping layer or metal barrier materials. Existing methods for improving the adhesion include increasing the ILD surface roughness through a surface pre-treatment using non-reactive gases such as argon or helium; modifying the surface chemistry via reactive ion etching, oxidative/reductive etching or ashing; and pre-treatment of the film with NH₃. The danger of modifying the surface chemistry is that the surface pre-treatment will undoubtedly change the chemical nature of both the surface and also the bulk of the material. Hence it might damage other film properties such as dielectric constant, thermal stability and chemical stability. Furthermore, gases that are used in etching contain fluorides which will leave some undesired fluoride containing residue in the ILD. The disadvantage of pre-treatment of the film with NH₃ is that any nitrogen containing species could potentially be poisonous in the lithography step if such nitrogen containing residue is not completely removed. Therefore there is a need to develop an adhesion promoter layer that can enhance the adhesion between the ILD or IMD and a capping or metal barrier material. Such adhesion promoter should also have little adverse effect on the film properties of the ILD and present few ill effects during the integration steps.

A prerequisite for the structures of the present invention is that the porous ILD or IMD must have good adhesion with the adhesion promoting layer. The present invention employs a dense spin-on, low k material as the adhesion promoter layer. Such a dense material allows for an intimate contact with either a capping material or a metal barrier material.

### SUMMARY OF THE INVENTION

The invention provides a multilayered dielectric structure which comprises:
a) a porous dielectric layer which has a porosity of about 10% or more;
b) an adhesion promoting dielectric layer on the porous dielectric layer which has a porosity of about 10% or less; and
c) a substantially nonporous capping layer on the adhesion promoting dielectric layer.

The invention also provides a microelectronic device which comprises a substrate, a porous dielectric layer on the substrate, said porous dielectric layer having a porosity of about 10% or more; an adhesion promoting dielectric layer on the porous dielectric layer which has a porosity of about 10% or less; and a substantially nonporous capping layer on the adhesion promoting dielectric layer.

The invention further provides a method for forming a multilayered dielectric structure comprising:
a) coating a substrate with a first composition comprising a pre-polymer, solvent, optional catalyst, and a porogen to form a film, cross-linking the composition to produce a gelled film, and heating the gelled film at a temperature and for a duration effective to remove substantially all of said porogen to produce a porous dielectric layer which has a porosity of about 10% or more;
b) coating the porous dielectric layer with a second composition comprising a silicon containing pre-polymer, solvent, and optional catalyst; followed by cross-linking and heating to produce an adhesion promoting dielectric layer on the porous dielectric layer which has a porosity of about 10% or less;
c) forming a substantially nonporous capping layer on the adhesion promoting dielectric layer.

### BRIEF DESCRIPTION OF THE DRAWING

FIG. 1 is a graph showing the correlations of tape test yield (% Pass) with silicon carbide thickness at a fixed NANOGLASS® E material and adhesion promoter thickness.

### DETAILED DESCRIPTION OF THE PREFERRED EMBODIMENT

A multilayered dielectric structure is formed by first producing a porous dielectric layer which has a porosity of about 10% Or more, suitably more than 10%. Preferably the porous dielectric layer has a porosity of from about 10% to about 90%, more preferably from about 20% to about 80% and most preferably from about 35% to about 60%. Preferably the porous dielectric layer has a dielectric constant of from about 1.3 to about 3.0, more preferably from about 1.5 to about 2.8 and most preferably from about 1.7 to about 2.5. The porous dielectric layer may comprise a nanoporous silica, silicon oxide, an organosilsesquioxane, such as methylsilsesquioxane, a polysiloxane, a porous organic polymer or combinations thereof. Typically, silicon-based dielectric films, including nanoporous silica dielectric films, are prepared from a composition comprising a suitable silicon containing pre-polymer, blended with a porogen and a catalyst which may be a metal-ion-free onium compound or a nucleophile. One or more optional solvents and/or other components may also be included. The dielectric precursor composition is applied to a substrate suitable, e.g., for production of a semiconductor device, such as an integrated circuit, by any art-known method to form a film. The composition is then crosslinked, such as by heating to produce a gelled film. The gelled film is then heated at a higher temperature to remove substantially all of the porogen.

The films produced by the processes of the invention have a number of advantages over those previously known to the art, including improved mechanical strength, that enables the produced film to withstand the further processing steps required to prepare a semiconductor device on the treated substrate, and a low and stable dielectric constant. The property of a stable dielectric constant is advantageously achieved without the need for further surface modification steps to render the film surface hydrophobic, as was formerly required by a number of processes for forming nanoporous silica dielectric films. Instead, the silica dielectric films are sufficiently hydrophobic as initially formed.

Further, the processes of the invention advantageously require a relatively low temperature for the initial polymerization (i.e., gelling or aging) of an applied prepolymer composition. The processes of the invention provided for a nanometer scale diameter pore size, which is also uniform in size distribution. The film typically has an average pore diameter ranging from about 1 nm to about 30 nm, or more preferably from about 1 nm to about 10 nm and typically from about 1 nm to about 5 nm.

It should be understood that the term nanoporous dielectric films, is intended to refer to dielectric films prepared by the inventive methods from an organic or inorganic glass base material, e.g., any suitable silicon-based material, Poly(arylene ether), polyimide or combinations thereof. Other examples include phenylethynylated-aromatic monomer or oligomer; fluorinated or non-fluorinated poly(arylene ethers) such as taught by commonly assigned U.S. Pat. Nos. 5,986,045; 6,124,421; 6,291,628 and 6,303,733; bisbenzocyclobutene; and organosiloxanes such as taught by commonly assigned U.S. Pat. No. 6,143,855 and pending U.S. patent application Ser. No. 10/078,919 filed Feb. 19, 2002 and Ser. No. 10/161,561 filed Jun. 3, 2002; Honeywell International Inc.'s commercially available HOSP® product; nanoporous silica such as taught by commonly assigned U.S. Pat. No. 6,372,666; Honeywell International Inc.'s commercially available NANOGLASS® E product; organosilsesquioxanes taught by commonly assigned WO 01/29052; and fluorosilsesquioxanes taught by commonly U.S. Pat. No. 6,440,550, incorporated herein in their entireties. Other useful dielectric materials are disclosed in commonly assigned pending patent applications PCT/US01/22204 filed Oct. 17, 2001 (claiming the benefit of our commonly assigned pending patent applications U.S. Ser. No. 09/545,058 filed Apr. 7, 2000; U.S. Ser. No. 09/618,945 filed Jul. 19, 2000; U.S. Ser. No. 09/897,936 filed Jul. 5, 2001; and U.S. Ser. No. 09/902,924 filed Jul. 10, 2001; and International Publication WO 0118110 published Oct. 18, 2001); PCT/US01/50812 filed Dec. 31, 2001; No. 60/______ filed May 30, 2002; No. 60/347,195 filed Jan. 8, 2002 and No. 60/384,303 filed May 30, 2002; No. 60/350,187 filed Jan. 15, 2002 and Ser. No. 10/160,773 filed May 30, 2002; and Ser. No. 10/158,513 filed May 30, 2002 and Ser. No. 10/158,548 filed May 30, 2002, which are incorporated herein by reference in their entireties. Additionally, the term “aging” refers to gelling, condensing, or polymerization, of the combined silica-based precursor composition on the substrate after deposition. The term “curing” refers to the removal of residual silanol (Si—OH) groups, removal of residual water, and the process of making the film more stable during subsequent processes of the microelectronic manufacturing process. The curing process is performed after gelling, typically by the application of heat, although any other art-known form of curing may be employed, e.g., by the application of energy in the form of an electron beam, ultraviolet radiation, and the like as taught by commonly assigned patent publication PCT/US96/08678 and U.S. Pat. Nos. 6,042,994; 6,080,526; 6,177,143; and 6,235,353, which are incorporated herein by reference in their entireties.

Dielectric films, e.g., interlevel dielectric coatings or metal level dielectrics, are prepared by applying suitable compositions to a substrate. Prior to application of the base materials to form the dielectric film, the substrate surface is optionally prepared for coating by standard, art-known cleaning methods. The coating is then processed to achieve the desired type and consistency of dielectric coating, wherein the processing steps are selected to be appropriate for the selected precursor and the desired final product. Further details of the inventive methods and compositions are provided below.

A substrate as used herein includes any suitable composition formed before a nanoporous silica film of the invention is applied to and/or formed on that composition. For example, a substrate is typically a silicon wafer suitable for producing an integrated circuit, and the material from which the nanoporous silica film is formed is applied onto the substrate. Substrates contemplated herein may comprise any desirable substantially solid material. Particularly desirable substrate layers comprise films, glass, ceramic, plastic, metal or coated metal, or composite material. In preferred embodiments, the substrate comprises a silicon or gallium arsenide die or wafer surface, a packaging surface such as found in a copper, silver, nickel or gold plated leadframe, a copper surface such as found in a circuit board or package interconnect trace, a via-wall or stiffener interface (“copper” includes bare copper and its oxides), a polymer-based packaging or board interface such as found in a polyimide-based flex package, lead or other metal alloy solder ball surface, glass and polymers. Useful substrates include silicon and compositions containing silicon such as crystalline silicon, polysilicon, amorphous silicon, epitaxial silicon, and silicon dioxide (“SiO₂”), silicon nitride, silicon oxide, silicon oxycarbide, silicon dioxide, silicon carbide, silicon oxynitride, organosiloxanes, organo silicon glass, fluorinated silicon glass, as well as titanium nitride, tantalum nitride, tungsten nitride, aluminum, copper, tantalum, polymers, gallium arsenide and combinations thereof. A circuit board comprising the multilayered structure will have mounted on its surface patterns for various electrical conductor circuits. The circuit board substrate may include various reinforcements, such as woven non-conducting fibers or glass cloth. Such circuit boards may be single sided, as well as double sided.

On the surface of the substrate is an optional pattern of raised lines, such as metal, oxide, nitride or oxynitride lines which are formed by well known lithographic techniques. Suitable materials for the lines include silica, silicon nitride, titanium nitride, tantalum nitride, aluminum, aluminum alloys, copper, copper alloys, tantalum, tungsten and silicon oxynitride. Useful metallic targets for making these lines are taught in commonly assigned U.S. Pat. Nos. 5,780,755; 6,238,494; 6,331,233B1; and 6,348,139B1 and are commercially available from Honeywell International Inc. These lines form the conductors or insulators of an integrated circuit. Such are typically closely separated from one another at distances of about 20 micrometers or less, preferably 1 micrometer or less, and more preferably from about 0.05 to about 1 micrometer. Other optional features of the surface of a suitable substrate include an oxide layer, such as an oxide layer formed by heating a silicon wafer in air, or more preferably, an SiO₂ oxide layer formed by chemical vapor deposition of such art-recognized materials as, e.g., plasma enhanced tetraethoxysilane oxide (“PETEOS”), plasma enhanced silane oxide (“PE silane”) and combinations thereof, as well as one or more previously formed nanoporous silica dielectric films.

The nanoporous silica film of the invention can be applied so as to cover and/or lie between such optional electronic surface features, e.g., circuit elements and/or conduction pathways that may have been previously formed features of the substrate. Such optional substrate features can also be applied above the nanoporous silica film of the invention in at least one additional layer, so that the low dielectric film serves to insulate one or more, or a plurality of electrically and/or electronically functional layers of the resulting integrated circuit. Thus, a substrate according to the invention optionally includes a silicon material that is formed over or adjacent to a nanoporous silica film of the invention, during the manufacture of a multilayer and/or multicomponent integrated circuit.

A crosslinkable composition employed for forming nanoporous silica dielectric films according to the invention includes one or more silicon containing prepolymers that are readily condensed. It should have at least two reactive groups that can be hydrolyzed. Such reactive groups include, alkoxy (RO), acetoxy (AcO), etc. Without being bound by any theory or hypothesis as to how the methods and compositions of the invention are achieved, it is believed that water hydrolyzes the reactive groups on the silicon monomers to form Si—OH groups (silanols). The latter will undergo condensation reactions with other silanols or with other reactive groups, as illustrated by the following formulas:
Si—OH+HO—Si→Si—O—S+H₂O
Si—OH+RO—Si→Si—O—Si+ROH
Si—OH+AcO—Si→Si—O—Si+AcOH
Si—OAc+AcO—Si→Si—O—Si+Ac₂O
R=alkyl or aryl
Ac=acyl (CH₃CO)
These condensation reactions lead to formation of silicon containing polymers. In one embodiment of the invention, the prepolymer includes a compound, or any combination of compounds, denoted by Formula I:
Rx-Si-Ly (Formula I)
wherein x is an integer ranging from 0 to about 2 and y is 4-x, an integer ranging from about 2 to about 4,
R is independently alkyl, aryl, hydrogen, alkylene, arylene and/or combinations of these,
L is independently selected and is an electronegative group, e.g., alkoxy, carboxyl, amino, amido, halide, isocyanato and/or combinations of these.

Particularly useful prepolymers are those provided by Formula I when x ranges from about 0 to about 2, y ranges from about 2 to about 4, R is alkyl or aryl or H, and L is an electronegative group, and wherein the rate of hydrolysis of the Si-L bond is greater than the rate of hydrolysis of the Si—OCH₂CH₃ bond. Thus, for the following reactions designated as (a) and (b):
(a) Si-L+H₂O→Si—OH+HL
(b) Si—OCH₂CH₃+H₂O→Si—OH+HOCH₂CH₃
   The rate of (a) is greater than rate of (b).

Examples of suitable compounds according to Formula I include, but are not limited to:
Si(OCH₂CF₃)₄ tetrakis(2,2,2-trifluoroethoxy)silane,
Si(OCOCF₃)₄ tetrakis(trifluoroacetoxy)silane*,
Si(OCN)₄ tetraisocyanatosilane,
CH₃Si(OCH₂CF₃)₃ tris(2,2,2-trifluoroethoxy)methylsilane,
CH₃Si(OCOCF₃)₃ tris(trifluoroacetoxy)methylsilane*,
CH₃Si(OCN)₃ methyltriisocyanatosilane,
   [*These generate acid catalyst upon exposure to water]
   and or combinations of any of the above.

In another embodiment of the invention, the composition includes a polymer synthesized from compounds denoted by Formula I by way of hydrolysis and condensation reactions, wherein the number average molecular weight ranges from about 150 to about 300,000 amu, or more typically from about 150 to about 10,000 amu.

In a further embodiment of the invention, silicon-containing prepolymers useful according to the invention include organosilanes, including, for example, alkoxysilanes according to Formula II:

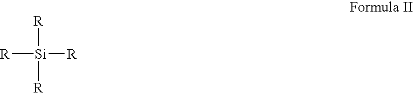

Optionally, Formula II is an alkoxysilane wherein at least 2 of the R groups are independently C₁ to C₄ alkoxy groups, and the balance, if any, are independently selected from the group consisting of hydrogen, alkyl, phenyl, halogen, substituted phenyl. For purposes of this invention, the term alkoxy includes any other organic groups which can be readily cleaved from silicon at temperatures near room temperature by hydrolysis. R groups can be ethylene glycoxy or propylene glycoxy or the like, but preferably all four R groups are methoxy, ethoxy, propoxy or butoxy. The most preferred alkoxysilanes nonexclusively include tetraethoxysilane (TEOS) and tetramethoxysilane.

In a further option, for instance, the prepolymer can also be an alkylalkoxysilane as described by Formula II, but instead, at least 2 of the R groups are independently C₁ to C₄ alkylalkoxy groups wherein the alkyl moiety is C₁ to C₄ alkyl and the alkoxy moiety in C₁ to C₆ alkoxy, or ether-alkoxy groups; and the balance, if any, are independently selected from the group consisting of hydrogen, alkyl, phenyl, halogen, substituted phenyl. In one preferred embodiment, each R is methoxy, ethoxy or propoxy. In another preferred embodiment, at least two R groups are alkylalkoxy groups wherein the alkyl moiety is C₁ to C₄ alkyl and the alkoxy moiety is C₁ to C₆ alkoxy. In yet another preferred embodiment for a vapor phase precursor, at least two R groups are ether-alkoxy groups of the formula (C₁ to C₆ alkoxy)ₙ wherein n is 2 to 6.

Preferred silicon containing prepolymers include, for example, any or a combination of alkoxysilanes such as tetraethoxysilane, tetrapropoxysilane, tetraisopropoxysilane, tetra(methoxyethoxy)silane, tetra(methoxyethoxyethoxy)silane which have four groups which may be hydrolyzed and than condensed to produce silica, alkylalkoxysilanes such as methyltriethoxysilane silane, arylalkoxysilanes such as phenyltriethoxysilane and precursors such as triethoxysilane which yield SiH functionality to the film. Tetrakis(methoxyethoxyethoxy)silane, tetrakis(ethoxyethoxy)silane, tetrakis(butoxyethoxyethoxy)silane, tetrakis(2-ethylthoxy)silane, tetrakis(methoxyethoxy)silane, and tetrakis(methoxypropoxy)silane are particularly useful for the invention.

In a still further embodiment of the invention, the alkoxysilane compounds described above may be replaced, in whole or in part, by compounds with acetoxy and/or halogen-based leaving groups. For example, the prepolymer may be an acetoxy (CH₃—CO—O—) such as an acetoxysilane compound and/or a halogenated compound, e.g., a halogenated silane compound and/or combinations thereof. For the halogenated prepolymers the halogen is, e.g., Cl, Br, I and in certain aspects, will optionally include F. Preferred acetoxy-derived prepolymers include, e.g., tetraacetoxysilane, methyltriacetoxysilane and/or combinations thereof.

In one particular embodiment of the invention, the silicon containing prepolymer includes a monomer or polymer precursor, for example, acetoxysilane, an ethoxysilane, methoxysilane and/or combinations thereof. In a more particular embodiment of the invention, the silicon containing prepolymer includes a tetraacetoxysilane, a C₁ to about C₆ alkyl or aryl-triacetoxysilane and combinations thereof. I particular, as exemplified below, the triacetoxysilane is a methyltriacetoxysilane.

The silicon containing prepolymer is preferably present in the overall composition in an amount of from about 10 weight percent to about 80 weight percent, preferably present in the overall composition in an amount of from about 20 weight percent to about 60 weight percent.

The composition preferably contains a catalyst. For non-microelectronic applications, the onium or nucleophile catalyst may contain metal ions. Examples include sodium hydroxide, sodium sulfate, potassium hydroxide, lithium hydroxide, and zirconium containing catalysts. For microelectronic applications, preferably, the composition preferably contains a metal-ion-free catalyst which may be, for example, an onium compound or a nucleophile. The catalyst may be, for example an ammonium compound, an amine, a phosphonium compound or a phosphine compound. Non-exclusive examples of such include tetraorganoammonium compounds and tetraorganophosphonium compounds including tetramethylammonium acetate, tetramethylammonium hydroxide, tetrabutylammonium acetate, triphenylamine, trioctylamine, tridodecylamine, triethanolamine, tetramethylphosphonium acetate, tetramethylphosphonium hydroxide, triphenylphosphine, trimethylphosphine, trioctylphosphine, and combinations thereof. The composition may comprise a non-metallic, nucleophilic additive which accelerates the crosslinking of the composition. These include dimethyl sulfone, dimethyl formamide, hexamethylphosphorous triamide (HMPT), amines and combinations thereof. The catalyst is preferably present in the overall composition in an amount of from about 1 ppm by weight to about 1000 ppm, preferably present in the overall composition in an amount of from about 6 ppm to about 200 ppm.

The composition then contains at least one porogen. A porogen may be a compound or oligomer or polymer and is selected so that, when it is removed, e.g., by the application of heat, a silica dielectric film is produced that has a nanometer scale porous structure. The scale of the pores produced by porogen removal is proportional to the effective steric diameters of the selected porogen component. The need for any particular pore size range (i.e., diameter) is defined by the scale of the semiconductor device in which the film is employed. Furthermore, the porogen should not be so small as to result in the collapse of the produced pores, e.g., by capillary action within such a small diameter structure, resulting in the formation of a non-porous (dense) film. Further still, there should be minimal variation in diameters of all pores in the pore population of a given film. It is preferred that the porogen is a compound that has a substantially homogeneous molecular weight and molecular dimension, and not a statistical distribution or range of molecular weights, and/or molecular dimensions, in a given sample. The avoidance of any significant variance in the molecular weight distribution allows for a substantially uniform distribution of pore diameters in the film of the inventive processes. If the produced film has a wide distribution of pore sizes, the likelihood is increased of forming one or more large pores, i.e., bubbles, that could interfere with the production of reliable semiconductor devices.

Furthermore, the porogen should have a molecular weight and structure such that it is readily and selectively removed from the film without interfering with film formation. This is based on the nature of semiconductor devices, which typically have an upper limit to processing temperatures. Broadly, a porogen should be removable from the newly formed film at temperatures below, e.g., about 450° C. In particular embodiments, depending on the desired post film formation fabrication process and materials, the porogen is selected to be readily removed at temperatures ranging from about 150° C. to about 450° C. during a time period ranging, e.g., from about 30 seconds to about 60 minutes. The removal of the porogen may be induced by heating the film at or above atmospheric pressure or under a vacuum, or by exposing the film to radiation, or both.

Porogens which meet the above characteristics include those compounds and polymers which have a boiling point, sublimation temperature, and/or decomposition temperature (at atmospheric pressure) range, for example, from about 150° C. to about 450° C. In addition, porogens suitable for use according to the invention include those having a molecular weight ranging, for example, from about 100 to about 50,000 amu, and more preferably in the range of from about 100 to about 3,000 amu.

Porogens suitable for use in the processes and compositions of the invention include polymers, preferably those which contain one or more reactive groups, such as hydroxyl or amino. Within these general parameters, a suitable polymer porogen for use in the compositions and methods of the invention is, e.g., a polyalkylene oxide, a monoether of a polyalkylene oxide, a diether of a polyallcylene oxide, bisether of a polyalkylene oxide, an aliphatic polyester, an acrylic polymer, an acetal polymer, a poly(caprolactone), a poly(valeractone), a poly(methyl methacrylate), a poly (vinylbutyral) and/or combinations thereof. When the porogen is a polyalkylene oxide monoether, one particular embodiment is a C₁ to about C₆ alkyl chain between oxygen atoms and a C₁ to about C₆ alkyl ether moiety, and wherein the alkyl chain is substituted or unsubstituted, e.g., polyethylene glycol monomethyl ether, polyethylene glycol dimethyl ether, or polypropylene glycol monomethyl ether.

Other useful porogens are porogens that do not bond to the silicon containing pre-polymer, and include a poly(alkylene) diether, a poly(arylene) diether, poly(cyclic glycol) diether, Crown ethers, polycaprolactone, fully end-capped polyalkylene oxides, fully end-capped polyarylene oxides, polynorbene, and combinations thereof. Preferred porogens which do not bond to the silicon containing pre-polymer include poly(ethylene glycol) dimethyl ethers, poly(ethylene glycol) bis(carboxymethyl) ethers, poly(ethylene glycol) dibenzoates, poly(ethylene glycol) diglycidyl ethers, a poly(propylene glycol) dibenzoates, poly(propylene glycol) diglycidyl ethers, poly(propylene glycol) dimethyl ether, 15-Crown 5,18-Crown-6, dibenzo-18-Crown-6, dicyclohexyl-18-Crown-6, dibenzo-15-Crown-5 and combinations thereof.

Without meaning to be bound by any theory or hypothesis, it is believed that porogens that are “readily removed from the film” undergo one or a combination of the following events: (1) physical evaporation of the porogen during the heating step, (2) degradation of the porogen into more volatile molecular fragments, (3) breaking of the bond(s) between the porogen and the Si containing component, and subsequent evaporation of the porogen from the film, or any combination of the preceding modes (1)-(3). The porogen is heated until a substantial proportion of the porogen is removed, e.g., at least about 50% by weight, or more, of the porogen is removed. More particularly, in certain embodiments, depending upon the selected porogen and film materials, at least about 75% by weight, or more, of the porogen is removed. Thus, by “substantially” is meant, simply by way of example, removing from about 50% to about 75%, or more, of the original porogen from the applied film. A porogen is preferably present in the overall composition, in an amount ranging from about 1 to about 50 weight percent, or more. More preferably the porogen is present in the composition, in an amount ranging from about 2 to about 20 weight percent. The greater the percentage of porogen employed, the greater is the resulting porosity.

The overall composition then optionally includes a solvent composition. Reference herein to a “solvent” should be understood to encompass a single solvent, polar or nonpolar and/or a combination of compatible solvents forming a solvent system selected to solubilize the overall composition components. A solvent is optionally included in the composition to lower its viscosity and promote uniform coating onto a substrate by art-standard methods. Suitable solvents for use in such solutions of the present compositions include any suitable pure or mixture of organic, organometallic, or inorganic molecules that are volatized at a desired temperature. In order to facilitate solvent removal, the solvent is one which has a relatively low boiling point relative to the boiling point of any selected porogen and the other precursor components. For example, solvents that are useful for the processes of the invention have a boiling point ranging from about 50° C. to about 250° C. to allow the solvent to evaporate from the applied film and leave the active portion of the precursor composition in place. In order to meet various safety and environmental requirements, the solvent preferably has a high flash point (generally greater than 40° C.) and relatively low levels of toxicity. A suitable solvent includes, for example, hydrocarbons, as well as solvents having the functional groups C—O—C (ethers), —CO—O (esters), —CO— (ketones), —OH (alcohols), and —CO—N-(amides), and solvents which contain a plurality of these functional groups, and combinations thereof.

Without limitation, suitable solvents include aprotic solvents, for example, cyclic ketones such as cyclopentanone, cyclohexanone, cycloheptanone, and cyclooctanone; cyclic amides such as N-alkylpyrrolidinone wherein the alkyl has from about 1 to 4 carbon atoms; and N-cyclohexylpyrrolidinone and mixtures thereof. A wide variety of other organic solvents may be used herein insofar as they are able to effectively control the viscosity of the resulting solution as a coating solution. Other suitable solvents include methyethylketone, methylisobutylketone, dibutyl ether, cyclic dimethylpolysiloxanes, butyrolactone, y-butyrolactone, 2-heptanone, ethyl 3-ethoxypropionate, 1-methyl-2-pyrrolidinone, and propylene glycol methyl ether acetate (PGMEA), and hydrocarbon solvents such as mesitylene, xylenes, benzene, and toluene. Other suitable solvents include di-n-butyl ether, anisole, acetone, 3-pentanone, 2-heptanone, ethyl acetate, n-propyl acetate, n-butyl acetate, ethyl lactate, ethanol, 2-propanol, dimethyl acetamide, propylene glycol methyl ether acetate, and/or combinations thereof. It is preferred that the solvent does not react with the silicon containing prepolymer component. The solvent component is preferably present in an amount of from about 10% to about 95% by weight of the overall composition. A more preferred range is from about 20% to about 75% and most preferably from about 20% to about 60%. The greater the percentage of solvent employed, the thinner is the resulting film.

In another embodiment the composition may comprises water, either as liquid or water vapor. For example, the overall composition may be applied to a substrate and then exposed to an ambient atmosphere that includes water vapor at standard temperatures and standard atmospheric pressure. Optionally, the composition is prepared prior to application to a substrate to include water in a proportion suitable for initiating aging of the precursor composition, without being present in a proportion that results in the precursor composition aging or gelling before it can be applied to a desired substrate. By way of example, when water is mixed into the precursor composition it is present in a proportion wherein the composition comprises water in a molar ratio of water to Si atoms in the silicon containing prepolymer ranging from about 0.1:1 to about 50:1. A more preferred range is from about 0.1:1 to about 10:1 and most preferably from about 0.5:1 to about 1.5:1.

Those skilled in the art will appreciate that specific temperature ranges for crosslinking and porogen removal from the nanoporous dielectric films will depend on the selected materials, substrate and desired nanoscale pore structure, as is readily determined by routine manipulation of these parameters. Generally, the coated substrate is subjected to a treatment such as heating to effect crosslinking of the composition on the substrate to produce a gelled film.

Crosslinking may be done by heating the film at a temperature ranging from about 100° C. to about 250° C., for a time period ranging from about 30 seconds to about 10 minutes to gel the film. The artisan will also appreciate that any number of additional art-known curing methods are optionally employed, including the application of sufficient energy to cure the film by exposure of the film to electron beam energy, ultraviolet energy, microwave energy, and the like, according to art-known methods.

Once the film has aged, i.e., once it is is sufficiently condensed to be solid or substantially solid, the porogen can be removed. The latter should be sufficiently non-volatile so that it does not evaporate from the film before the film solidifies. The porogen is removed by heating the gelled film at a temperature ranging from about 150° C. to about 450° C., preferably from about 150° C. to about 350° C. for a time period ranging from about 30 seconds to about 1 hour. Preferably the crosslinking is conducted at a temperature which is less than the porogen removal temperature.

The present layers may also comprise additional components such as antifoam agents, detergents, flame retardants, pigments, plasticizers, stabilizers, and surfactants. The composition is particularly useful in microelectronic applications as a dielectric substrate material in microchips, multichip modules, laminated circuit boards, or printed wiring boards.

The films may be formed on the substrate by solution techniques such as spraying, rolling, dipping, spin coating, flow coating, or casting, or chemical vapor deposition, with spin coating being preferred for microelectronics. For chemical vapor deposition (CVD), the composition is placed into an CVD apparatus, vaporized, and introduced into a deposition chamber containing the substrate to be coated. Vaporization may be accomplished by heating the composition above its vaporization point, by the use of vacuum, or by a combination of the above. Generally, vaporization is accomplished at temperatures in the range of 50° C.-300° C. under atmospheric pressure or at lower temperature (near room temperature) under vacuum.

Three types of CVD processes exist: atmospheric pressure CVD (APCVD), low pressure CVD (LPCVD), and plasma enhanced CVD (PECVD). Each of these approaches had advantages and disadvantages. APCVD devices operate in a mass transport limited reaction mode at temperatures of approximately 400° C. In mass-transport limited deposition, temperature control of the deposition chamber is less critical than in other methods because mass transport processes are only weakly dependent on temperature. As the arrival rate of the reactants is directly proportional to their concentration in the bulk gas, maintaining a homogeneous concentration of reactants in the bulk gas adjacent to the wafers is critical. Thus, to insure films of uniform thickness across a wafer, reactors that are operated in the mass transport limited regime must be designed so that all wafer surfaces are supplied with an equal flux of reactant. The most widely used APCVD reactor designs provide a uniform supply of reactants by horizontally positioning the wafers and moving them under a gas stream.

In contrast to APCVD reactors, LPCVD reactors operate in a reaction rate-limited mode. In processes that are run under reaction rate-limited conditions, the temperature of the process is an important parameter. To maintain a uniform deposition rate throughout a reactor, the reactor temperature must be homogeneous throughout the reactor and at all wafer surfaces. Under reaction rate-limited conditions, the rate at which the deposited species arrive at the surface is not as critical as constant temperature. Thus, LPCVD reactors do not have to be designed to supply an invariant flux of reactants to all locations of a wafer surface.

Under the low pressure of an LPCVD reactor, for example, operating at medium vacuum (30-250 Pa or 0.25-2.0 torr) and higher temperature (550-600° C.), the diffusivity of the deposited species is increased by a factor of approximately 1000 over the diffusivity at atmospheric pressure. The increased diffusivity is partially offset by the fact that the distance across which the reactants must diffusive increases by less than the square root of the pressure. The net effect is that there is more than an order of magnitude increase in the transport of reactants to the substrate surface and by-products away from the substrate surface.

LPCVD reactors are designed in two primary configurations: (a) horizontal tube reactors; and (b) vertical flow isothermal reactors. Horizontal tube, hot wall reactors are the most widely used LPCVD reactors in VLSI processing. They are employed for depositing poly-Si, silicon nitride, and undoped and doped SiO₂ films. They find such broad applicability primarily because of their superior economy, throughput, uniformity, and ability to accommodate large diameter, e.g., 150 mm, wafers.

The vertical flow isothermal LPCVD reactor further extends the distributed gas feed technique so that each wafer receives an identical supply of fresh reactants. Wafers are again stacked side by side, but are placed in perforated-quartz cages. The cages are positioned beneath long, perforated, quartz reaction-gas injector tubes, one tube for each reactant gas. Gas flows vertically from the injector tubes, through the cage perforations, past the wafers, parallel to the wafer surface and into exhaust slots below the cage. The size, number, and location of cage perforations are used to control the flow of reactant gases to the wafer surfaces. By properly optimizing cage perforation design, each wafer may be supplied with identical quantities of fresh reactants from the vertically adjacent injector tubes. Thus, this design may avoid the wafer-to-wafer reactant depletion effects of the end-feed tube reactors, requires no temperature ramping, produces highly uniform depositions, and reportedly achieves low particulate contamination.

The third major CVD deposition method is PECVD. This method is categorized not only by pressure regime, but also by its method of energy input. Rather than relying solely on thermal energy to initiate and sustain chemical reactions, PECVD uses an rf-induced glow discharge to transfer energy into the reactant gases, allowing the substrate to remain at a lower temperature than in APCVD or LPCVD processes. Lower substrate temperature is the major advantages of PECVD, providing film deposition on substrates not having sufficient thermal stability to accept coating by other methods. PECVD may also enhance deposition rates over those achieved using thermal reactions. Moreover, PECVD may produce films having unique compositions and properties. Desirable properties such as good adhesion, low pinpole density, good step coverage, adequate electrical properties, and compatibility with fine-line pattern transfer processes, have led to application of these films in VLSI.

PECVD requires control and optimization of several deposition parameters, including rf power density, frequency, and duty cycle. The deposition process is dependent in a complex and interdependent way on these parameters, as well as on the usual parameters of gas composition, flow rates, temperature, and pressure. Furthermore, as with LPCVD, the PECVD method is surface reaction limited, and adequate substrate temperature control is thus necessary to ensure uniform film thickness.

CVD systems usually contain the following components: gas sources, gas feed lines, mass-flow controllers for metering the gases into the system, a reaction chamber or reactor, a method for heating the wafers onto which the film is to be deposited, and in some types of systems, for adding additional energy by other means, and temperature sensors. LPCVD and PECVD systems also contain pumps for establishing the reduced pressure and exhausting the gases from the chamber.

The thickness of the porous dielectric layer may range from about 500 Å to about 20,000 Å, preferably from about 1000 Å to about 14,000 Å and more preferably from about 1500 Å to about 10,000 Å.

Applied onto the porous dielectric layer is an adhesion promoting dielectric layer, which may also act as a stress buffer, which has a porosity of about 10% or less. The materials of method of forming the an adhesion promoting dielectric layer may be the same as that for the porous dielectric layer except the amounts of porogen and solvent are chosen such that a dielectric layer is produced which has a porosity of about 10% or less, preferably less than 10% and more preferably from about 0.1% to about 10%.

Preferably, the adhesion promoting dielectric layer may be formed by preparing a composition containing the same ingredients as the porous dielectric layer except the porogen is much reduced or preferably omitted completely. The adhesion promoting dielectric layer has a dielectric constant of about 2.8 or more. Preferably the adhesion promoting dielectric layer has a dielectric constant of from about 2.8 to about 4.0, more preferably from about 2.9 to about 3.3 and most preferably from about 3.0 to about 3.2. Preferably the combination of the porous dielectric layer and the adhesion promoting dielectric layer has an effective dielectric constant of from about 1.4 to about 3.0, more preferably from about 1.7 to about 2.8. The phrase “effective dielectric constant” as used here means dielectric constant of film stack of the porous dielectric layer and the adhesion promoting dielectric layer. The thickness of the adhesion promoting dielectric layer may range from about 1 Å to about 3000 Å, preferably from about 5 Å to about 2000 Å and more preferably from about 10 Å to about 800 Å. Preferably the ratio of the thickness of the adhesion promoting layer to the sum of the adhesion promoting layer and the porous dielectric layer ranges from about 0.02 to about 0.30, more preferably from about 0.02 to about 0.25 and most preferably from about 0.03 to about 0.15. Preferably the coating of the adhesion promoting dielectric layer onto the porous dielectric layer results in an infiltration of the adhesion promoting dielectric layer into the porous dielectric layer of about 300 angstroms or less.

On the adhesion promoting dielectric layer, is a substantially nonporous capping layer. Suitable capping layers include silicon carbide, silicon oxide, silicon nitride, silicon oxynitride, tungsten, tungsten nitride, tantalum, tantalum nitride, titanium, titanium nitride, titanium zirconium nitride, and combinations thereof. The capping layer may be applied to the adhesion promoting layer by any known technique such as spin coat or CVD processes. Preferably the capping layer has a dielectric constant of from about 2.8 to about 7.0, more preferably from about 4.0 to about 7.0. The thickness of the capping layer may range from about 200 Å to about 3000 Å, preferably from about 300 Å to about 2500 Å and more preferably from about 500 Å to about 2000 Å. The adhesion promoting dielectric layer, the porous dielectric layer, and the capping layer are adhered to one another to a degree sufficient to pass the ASTM D 3359-97 test.

The multilayered structure may be used in electrical devices and more specifically, as an interlayer dielectric in an interconnect associated with a single integrated circuit chip. An integrated circuit chip typically has on its surface a plurality of layers of the present multilayered structure and multiple layers of metal conductors. It may also include regions of the present multilayered structure between discrete metal conductors or regions of conductor in the same layer or level of an integrated circuit.

The present multilayered structures may be used in dual damascene (such as copper) processing and subtractive metal (such as aluminum or aluminum/tungsten) processing for integrated circuit manufacturing. The present multilayered structures may be used in a desirable all spin-on stacked film having additional dielectrics such as taught by commonly assigned U.S. Pat. Nos. 6,248,457B1; 5,986,045; 6,124,411; and 6,303,733.

Analytical Test Methods:

Dielectric Constant: The dielectric constant was determined by coating a thin film of aluminum on the cured layer and then doing a capacitance-voltage measurement at 1 MHz and calculating the k value based on the layer thickness.

Average Pore Size Diameter: The N₂ isotherms of porous samples was measured on a Micromeretics ASAP 2000 automatic isothermal N₂ sorption instrument using UHP (ultra high purity industrial gas) N₂, with the sample immersed in a sample tube in a liquid N₂ bath at 77° K.

For sample preparation, the material was first deposited on silicon wafers using standard processing conditions. For each sample, three wafers were prepared with a film thickness of approximately 6000 Angstroms. The films were then removed from the wafers by scraping with a razor blade to generate powder samples. These powder samples were pre-dried at 180° C. in an oven before weighing them, carefully pouring the powder into a 10 mm inner diameter sample tube, then degassing at 180° C. at 0.01 Torr for >3 hours.

The adsorption and desorption N₂ sorption was then measured automatically using a 5 second equilibration interval, unless analysis showed that a longer time was required. The time required to measure the isotherm was proportional to the mass of the sample, the pore volume of the sample, the number of data points measured, the equilibration interval, and the P/Po tolerance. (P is the actual pressure of the sample in the sample tube. Po is the ambient pressure outside the instrument.) The instrument measures the N₂ isotherm and plots N₂ versus P/Po.

The apparent BET (Brunauer, Emmett, Teller method for multi-layer gas absorption on a solid surface disclosed in S. Brunauer, P. H. Emmett, E. Teller; J. Am. Chem. Soc. 60, 309-319 (1938)) surface area was calculated from the lower P/Po region of the N2 adsorption isotherm using the BET theory, using the linear section of the BET equation that gives an R² fit>0.9999.

The pore volume was calculated from the volume of N₂ adsorbed at the relative pressure P/Po value, usually P/Po˜0.95, which is in the flat region of the isotherm where condensation is complete, assuming that the density of the adsorbed N₂ is the same as liquid N₂ and that all the pores are filled with condensed N₂ at this P/Po.

The pore size distribution was calculated from the adsorption arm of the N₂ isotherm using the BJH (E. P. Barret, L. G. Joyner, P. P. Halenda; J. Am. Chem. Soc., 73, 373-380 (1951)) theory. This uses the Kelvin equation, which relates curvature to suppression of vapor pressure, and the Halsey equation, which describes the thickness of the adsorbed N₂ monolayer versus P/Po, to convert the volume of condensed N₂ versus P/Po to the pore volume in a particular range of pore sizes.

The average cylindrical pore diameter D was the diameter of a cylinder that has the same apparent BET surface area Sa (m²/g) and pore volume Vp (cc/g) as the sample, so D (nm)=4000 Vp/Sa.

Refractive Index: The refractive index measurements were performed together with the thickness measurements using a J. A. Woollam M-88 spectroscopic ellipsometer. A Cauchy model was used to calculate the best fit for Psi and Delta. Unless noted otherwise, the refractive index was reported at a wavelenth of 633 nm (details on Ellipsometry can be found in e.g. “Spectroscopic Ellipsometry and Reflectometry” by H. G. Thompkins and William A. McGahan, John Wiley and Sons, Inc., 1999).

Adhesion: The sample was prepared and tested according to ASTM D3359-97.

Chemical Mechanical Polishing (CMP) was conducted under the following condition. The polisher is IPEC 472. The slurry being used was EKC Cu Phase II, silica-based slurry for barrier Ta/TaN removal, and the slurry flow rate was 200 cc/min. The primary pad was the Rodel IC1400/SubaIV, K-groove, where as the secondary pad was the Polytex. The conditioning disk was the Marshal whirlpool 4″ diamond disk, and the post CMP) cleaning was conducted with the OnTrak Synergy using DI water as the solvent.

The following non-limiting examples serve to illustrate the invention.

### EXAMPLES

A porous dielectric layer which has a porosity of about 10% or more was produced as follows. This porous dielectric layer is employed in the following examples.

Crude PEO (polyethylene glycol monomethyl ether MW=550) with high concentration of sodium was purified by mixing the crude PEO with water in a 50:50 weight ratio. This mixture was passed through an ion exchange resin to remove metals. The filtrate was collected and subjected to vacuum distillation to remove water to produce neat, low metal PEO (with <100 ppb Na). A precursor was prepared by combining, in a 100 ml round bottom flask (containing a magnetic stirring bar), 10 g tetraacetoxysilane, 10 g methyltriacetoxysilane, and 17 g propylene glycol methyl ethyl acetate (PGMEA). These ingredients were combined within an N₂-environment (N₂ glove bag). The flask was also connected to an N₂ environment to prevent environmental moisture from entering the solution (standard temperature and pressure).

The reaction mixture was heated to 80° C. before 1.5 g of water was added to the flask. After the water addition is complete, the reaction mixture was allowed to cool to ambient before 4.26 g of low metal polyethylene glycol monomethylether (“PEO”; MW550 amu) (with >300 ppb Na) was added as a porogen and tetraorganoammonium acetate (TMAA, 19×10⁻⁸ mole/gm of solution, which corresponds to approximately 10 ppm of TMAA by weight) was added as a catalyst, and stirring continued for another 2 hrs. Thereafter, the resulting solution was filtered through a 0.2 micron filter to provide the precursor solution masterbatch for the next step.

The solution was then deposited onto a series of 8-inch silicon wafers, each on a spin chuck and spun at 2500 rpm for 30 seconds. The presence of water in the precursor resulted in the film coating being substantially condensed by the time that the wafer was inserted into the first oven. Insertion into the first oven, as discussed below, takes place within the 10 seconds of the completion of spinning. Each coated wafer was then transferred into a sequential series of ovens preset at specific temperatures, for one minute each. In this example, there are three ovens, and the preset oven temperatures were 125° C., 200° C., and 350° C., respectively. The PEO was driven off by these sequential heating steps as each wafer was moved through each of the three respective ovens. Each wafer was cooled after receiving the three-oven stepped heat treatment, and the produced dielectric film was measured using ellipsometry to determine its thickness and refractive index. Each film-coated wafer was then further cured at 425° C. for one hour under flowing nitrogen. A non-porous film made from the liquid precursor of this invention will have a refractive index of 1.41 and a k_{de-gas} of 3.2. In comparison, air has a refractive index of 1.0. The porosity of a nanoporous film of the invention, is therefore proportional to the percentage of its volume that is air. The film has a bake thickness of 5920 Å, a bake refractive index of 1.234, a cure thickness of 5619 Å and a cure refractive index of 1.231. The cured film produced has a porosity of about 43%. The capacitance of the film was measured after heating the wafer in a hot plate at 200C for 2 minutes in order to drive off adsorbed moisture. Dielectric constant based on the de-moisture capacitance is called k de-gas.

### EXAMPLE 1

### Comparative

A series of 8-inch silicon wafers was deposited with a layer of cured film of the above porous dielectric layer (300 or 600 nm). A CVD capping layer (200 nm of SiC or SiO₂) was deposited onto the porous dielectric film layer in the absence of an adhesion promoting dielectric layer. Entries 1, 4 and 9 illustrate poor adhesion of the porous dielectric layer to either a SiC or SiO₂ capping layer in the absence of an adhesion promoting dielectric layer. A tape test was performed according to the standard test method (ASTM D 3359-97). It was observed that the adhesion of the porous dielectric layer to the capping layer is inferior and the CVD capping layer was easily removed.

### EXAMPLE 2

### Comparative

A PGMEA solution of hydridopolycarbosilanes was deposited onto a series of 8-inch silicon wafers (pre-coated with the porous dielectric layer produced above, 300 nm), each on a spin chuck and spun at 2400 rpm for 30 seconds. The wafer was then inserted into the first oven. Insertion into the first oven, as discussed below, took place within the 10 seconds of the completion of spinning. Each coated wafer was then transferred into a sequential series of ovens preset at specific temperatures, for one minute each. In this example, there are three ovens, and the preset oven temperatures were 125° C., 200° C., and 350° C., respectively. Each wafer was cooled after receiving the three-oven stepped heat treatment, and the produced stacked dielectric film was measured using ellipsometry to determine its thickness and refractive index. Each stack film-coated wafer was then further cured at 425° C. for one hour under flowing nitrogen. The film thickness could not be measured due to extremely poor quality. A CVD capping layer (200 nm of SiO₂ for entry 14) was then deposited onto the film stack of adhesion promoter and the porous dielectric layer. A tape test was performed according to the standard test method (ASTM D 3359-97). It was observed that the adhesion of the porous dielectric layer to the capping layer is inferior and the CVD capping layer was easily removed. The resulting film showed very poor adhesions (<10% pass).

### EXAMPLE 3

This example shows the production of an adhesion promoter.

An adhesion promoter precursor was prepared by combining, in a reaction flask, a matrix formed by first mixing 233 g of tetraacetoxysilane and 233 g of methyltriacetoxysilane followed by heating at 80° C. and then adding 35 g of water and cooling the reaction mixture to room temperature. Then 2794 g of propylene glycol methyl ethyl acetate (PGMEA), and 2.5 g of 1% solution of tetramethylammonium acetate in acetic acid (TMAA) are added. The solution was stirred for 2 h, and filtered. The solution was then deposited onto a series of 8-inch silicon wafers (pre-coated with the porous dielectric layer produced above, 300 nm), each on a spin chuck and spun at 2000 rpm for 30 seconds. The presence of water in the precursor resulted in the film coating being substantially condensed by the time that the wafer was inserted into the first oven. Insertion into the first oven, as discussed below, took place within the 10 seconds of the completion of spinning. Each coated wafer was then transferred into a sequential series of ovens preset at specific temperatures, for one minute each. In this example, there are three ovens, and the preset oven temperatures were 125° C., 200° C., and 350° C., respectively. Each wafer was cooled after receiving the three-oven stepped heat treatment, and the produced stacked dielectric film was measured using ellipsometry to determine its thickness and refractive index. Each stack film-coated wafer was then further cured at 425° C. for one hour under flowing nitrogen. The film has a cure thickness of 40 and 290 nm for the adhesion promoter layer and the porous dielectric layer, respectively. A CVD capping layer (200 nm of SiC for entry 3 or 200 nm of SiO₂ for entry 11) was then deposited onto the film stack of adhesion promoter and the porous dielectric layer.

The tape test was performed according to the standard method, and it revealed that the adhesion of the resulting film stack is excellent showing no signs of delaminations. An additional CMP (“Chemical Mechanical Polishing”) process also indicates that the stack film can survive conditions such as a 5 psi down force for 120 s.

### EXAMPLE 4

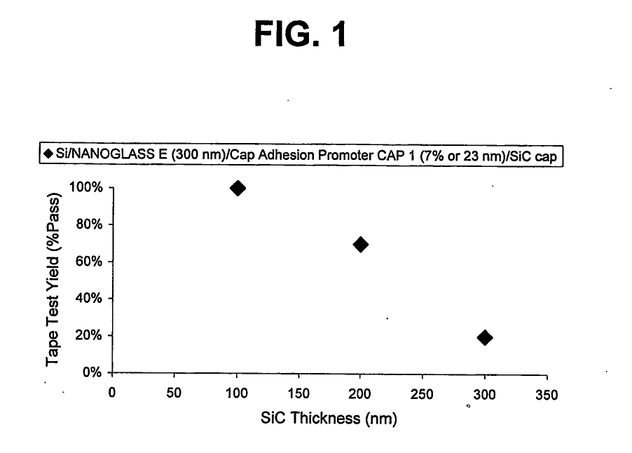

Example 2 is repeated except this example (see entries 2, 7 and 8) has a 23 nm layer (ca. 7%) of adhesion promoter coated on the porous dielectric layer (300 nm). Various thicknesses of silicon carbide were also deposited (100 (entry 7), 200 (entry 2) and 300 nm (entry 8)). The tape test results revealed that the adhesion strength depends on the SiC cap thickness. Entry 7 indicates that the adhesion is excellent when there is only a 100 nm of SiC cap. An increase in SiC cap thickness to 200 nm results in a reduced tape test yield of 70%. An even higher SiC cap thickness (300 nm) leads to a much worse tape test yield (20%).(see FIG. 1)

### EXAMPLE 5

Example 2 is repeated except the porous dielectric layer has a thickness of 600 nm, and the SiC cap thickness is fixed at 200 nm. Two different thickness of adhesion promoter are coated onto the porous dielectric layer. Entry 5 shows that adhesion is poor, showing 80% of delaminations when the adhesion promoter layer is only 4% (or 25 nm). However, after the adhesion promoter layer thickness is increased to 10% (or 60 nm), the resulting film stack exhibits excellent adhesion as shown in entry 6.

### EXAMPLE 6

Example 2 is repeated except that only 25 nm (or 8%) of the adhesion promoter layer was deposited onto the porous dielectric layer (300 nm), followed by the CVD deposition of 200 nm of SiO₂.

Subjecting the resulting film stack (entry 10) to the standard tape test revealed 80% delaminations.

### EXAMPLE 7

This example (entry 13) describes the utilization of a commercially available methylsiloxane polymer (Honeywell ACCUGLASS® SPIN-ON GLASS T12B material) as an adhesion promoter.

ACCUGLASS® SPIN-ON GLASS T12B solution was deposited onto a series of 8-inch silicon wafers (pre-coated with the porous dielectric layer, 300 nm), each on a spin chuck and spun at 2000 rpm for 30 seconds. The presence of water in the precursor resulted in the film coating being substantially condensed by the time that the wafer was inserted into the first oven. Insertion into the first oven, as discussed below, took place within the 10 seconds of the completion of spinning. Each coated wafer was then transferred into a sequential series of ovens preset at specific temperatures, for one minute each. In this example, there are three ovens, and the preset oven temperatures were 125° C., 200° C., and 350° C., respectively. Each wafer was cooled after receiving the three-oven stepped heat treatment, and the produced stacked dielectric film was measured using ellipsometry to determine its thickness and refractive index. Each stack film-coated wafer was then further cured at 425° C. for one hour under flowing nitrogen. The film has a cure thickness of 40 and 280 nm for the adhesion promoter layer and the porous dielectric layer, respectively.

A CVD cap (200 nm of SiO₂) was then deposited onto the film stack of adhesion promoter and the porous dielectric layer. The tape test was performed according to the standard method, and it revealed that the adhesion of the resulting film stack is excellent, showing no signs of delaminations. Additional CMP process also indicates that the stack film can survive conditions such as 5 psi down force for 120 s.

### EXAMPLE 8

Example 6 is repeated except that only 25 nm of ACCUGLASS® SPIN-ON GLASS T12B was coated onto the porous dielectric layer (8% or 280 nm, entry 12). Because of the reduction in adhesion promoter layer thickness, the resulting film shows a 40% delaminations by the tape test.

TABLE

| | Thickness | Adhesion | | CAP Thick- | | Tape | CMP³ |
|---|---|---|---|---|---|---|---|
| | (nm) | Promoter | | ness (nm) | | Test | Obser- |
| | ILD | Type¹ | Fraction² | SiC | SiO₂ | % Pass | vation |
| 1 | 300 | None | | 200 | | 0 | FAILED |
| 2 | 300 | A | 7% | 200 | | 70 | PASS |
| 3 | 300 | A | 12% | 200 | | 100 | PASS |
| 4 | 600 | None | | 200 | | 0 | FAILED |
| 5 | 600 | A | 4% | 200 | | 20 | PASS |
| 6 | 600 | A | 10% | 200 | | 100 | PASS |
| 7 | 300 | A | 7% | 100 | | 100 | PASS |
| 8 | 300 | A | 7% | 300 | | 20 | PASS |
| 9 | 300 | None | | | 200 | 0 | FAILED |
| 10 | 300 | A | 8% | | 200 | 20 | PASS |
| 11 | 300 | A | 12% | | 200 | 100 | PASS |
| 12 | 300 | B | 8% | | 200 | 60 | PASS |
| 13 | 300 | B | 10% | | 200 | 100 | PASS |
| 14 | 300 | C | — | | 200 | <10 | FAILED |

¹A = the porous dielectric layer; B = ACCUGLASS ® SPIN-ON GLASS T12B and C = Hydridopolycarbosilanes
²Fraction = ratio of the thickness of the adhesion promoting dielectric layer to the total thickness of the adhesion promoting dielectric layer and the porous dielectric layer;
³C(hemical)M(echanical)P(olishing) condition is described in detail in the experimental section. PASS = no delaminations. FAILED = delaminations.

While the present invention has been particularly shown and described with reference to preferred embodiments, it will be readily appreciated by those of ordinary skill in the art that various changes and modifications may be made without departing from the spirit and scope of the invention. It is intended that the claims be interpreted to cover the disclosed embodiment, those alternatives which have been discussed above and all equivalents thereto.

1. A multilayered dielectric structure which comprises:
a) a porous dielectric layer which has a porosity of about 10% or more;
b) an adhesion promoting dielectric layer on the porous dielectric layer which has a porosity of about 10% or less; and
c) a substantially nonporous capping layer on the adhesion promoting dielectric layer.

2. The structure of claim 1 wherein the porous dielectric layer is further disposed on a substrate.

3. The structure of claim 1 wherein the porous dielectric layer has a porosity of from about 10% to about 90%.

4. The structure of claim 1 wherein the porous dielectric layer has a dielectric constant of from about 1.3 to about 3.0.

5. The structure of claim 1 wherein the combination of the porous dielectric layer and the adhesion promoting dielectric layer has an effective dielectric constant of from about 1.4 to about 3.0.

6. The structure of claim 1 wherein the porous dielectric layer comprises a material selected from the group consisting of a nanoporous silica, silicon oxide, an organosilsesquioxane, a polysiloxane, a poly(arylene ether), a polyimide and combinations thereof.

7. The structure of claim 1 wherein the adhesion promoting dielectric layer has a porosity of from about 0.1% to about 13%.

8. The structure of claim 1 wherein the adhesion promoting dielectric layer has a dielectric constant of about 2.8 or more.

9. The structure of claim 1 wherein the adhesion promoting dielectric layer has a dielectric constant of from about 2.8 to about 4.0.

10. The structure of claim 1 wherein the adhesion promoting dielectric layer comprises a material selected from the group consisting of a nanoporous silica, silicon oxide, an organosilsesquioxane, a polysiloxane, a poly(arylene ether), a polyimide and combinations thereof.

11. The structure of claim 1 wherein the capping layer has a dielectric constant of from about 2.8 to about 7.0.

12. The structure of claim 1 wherein the capping layer comprises a material selected from the group consisting of silicon carbide, silicon oxide, silicon nitride, silicon oxynitride, tungsten, tungsten nitride, tantalum, tantalum nitride, titanium, titanium nitride, titanium zirconium nitride, and combinations thereof.

13. The structure of claim 1 wherein the ratio of the thickness of the adhesion promoting dielectric layer to the total thickness of the adhesion promoting dielectric layer and the porous dielectric layer ranges from about 0.02 to about 30.

14. The structure of claim 1 wherein the adhesion promoting dielectric layer, the porous dielectric layer, and the capping layer are adhered to one another to a degree sufficient to pass the ASTM D 3359-97 test.

15. A microelectronic device which comprises a substrate, a porous dielectric layer on the substrate, said porous dielectric layer having a porosity of about 10% or more; an adhesion promoting dielectric layer on the porous dielectric layer which has a porosity of about 10% or less; and a substantially nonporous capping layer on the adhesion promoting dielectric layer.

16. A method for forming a multilayered dielectric structure comprising:
a) coating a substrate with a first composition comprising a pre-polymer, solvent, optional catalyst, and a porogen to form a film, cross-linking the composition to produce a gelled film, and heating the gelled film at a temperature and for a duration effective to remove substantially all of said porogen to produce a porous dielectric layer which has a porosity of about 10% or more;
b) coating the porous dielectric layer with a second composition comprising a silicon containing pre-polymer, solvent, and optional catalyst; followed by cross-linking and heating to produce an adhesion promoting dielectric layer on the porous dielectric layer which has a porosity of about 10% or less; and
c) forming a substantially nonporous capping layer on the adhesion promoting dielectric layer.

17. The method of claim 16 wherein the second composition is absent of a porogen.

18. The method of claim 16 wherein the first composition and the second composition comprises a metal-ion-free catalyst selected from the group consisting of onium compounds and nucleophiles.

19. The method of claim 16 wherein the first composition comprises a porogen which is selected from the group consisting of a polyalkylene oxide, a monoether of a polyalkylene oxide, fully end-capped polyalkylene oxides, Crown ethers, an aliphatic polyester, an acrylic polymer, an acetal polymer, a poly(caprolatactone), a poly(valeractone), a poly(methyl methacrylate), a poly (vinylbutyral) and combinations thereof.

20. The method of claim 16 wherein the first composition and the second composition comprises a silicon containing pre-polymer selected from the group consisting of an acetoxysilane, an ethoxysilane, a methoxysilane, and combinations thereof.

21. The method of 16 wherein the coating of the second composition onto the porous dielectric layer results in an infiltration of the second composition into the porous dielectric layer of about 300 angstroms or less.

22. The method of claim 16 wherein the first composition and the second composition comprises a silicon containing pre-polymer selected from the group consisting of tetraacetoxysilane, a C₁ to about C₆ alkyl or aryl-triacetoxysilane, and combinations thereof.

23. The method of claim 22 wherein said triacetoxysilane is methyltriacetoxysilane.
